(19) United States
(12) Patent Application Publication
(10) Pub. No.: US 2010/0072486 A1
(43) Pub. Date: Mar. 25, 2010

(54) WAVELENGTH CONVERTING ELEMENTS WITH REFLECTIVE EDGES

(75) Inventors: Paulus Hubertus Gerardus Offermans, Eindhoven (NL); Emanuel Johannes Wilhelmus Maria Lenders, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/513,380

(22) PCT Filed: Oct. 30, 2007
(86) PCT No.: PCT/IB07/54394

§ 371 Date: May 4, 2009

(30) Foreign Application Priority Data
Nov. 6, 2006 (EP) 06123495.1

(51) Int. Cl. H01L 33/00

(52) U.S. Cl. 257/84; 438/24; 257/E33.077

(57) ABSTRACT

A light emitting device (1) is provided and comprises a light emitting diode (2) and a self-supporting wavelength converting element (3) arranged to receive at least part of the light emitted by said light emitting diode (2). The wavelength converting element has a flat light receiving surface (4), a light output surface (5) and lateral edge surfaces (6), wherein said lateral edge surfaces (6) are provided with a reflecting material (7). The reflecting edge surfaces increases the color homogeneity of the light exiting the device and the device is suitable for mass production.

### FIELD OF THE INVENTION

The present invention relates to a light-emitting device comprising a light emitting diode and a self-supporting wavelength converting element arranged to receive at least part of the light emitted by the light emitting diode, to the wavelength-converting element as such, and to methods for the manufacture of such elements and devices.

### BACKGROUND OF THE INVENTION

Semiconductor light-emitting devices comprising light-emitting diodes (LEDs) are among the most efficient and robust light sources currently available. Illumination requires white color light sources, in particular white light sources of high color rendering properties. Various attempts have been made to make white light emitting illumination systems by using LEDs as radiation sources.

One method of obtaining white light is to use blue LEDs and convert part of the emitted blue light to yellow light (wavelength spectrum at about 580 nm) via phosphors. Since yellow light stimulates the red and green receptors of the eye, the resulting mix of blue and yellow light gives the appearance of white.

Typically, this is done by arranging a phosphor-containing material, a wavelength converting material on the LED such that part of the light emitted by the LED is absorbed by the phosphors and is emitted as light of a wavelength different from that of the absorbed light.

However, one problem associated with such an arrangement is the color homogeneity of the light provided. Light emitted from the edges of the LED and at oblique angles from the LED will not pass through the same thickness of wavelength converting material as light emitted in a forward direction. Hence, typically the degree of conversion of light exiting through the lateral sides of the material is lower than for the light exiting through the front surface of the material. Hence, a blue ring of light will be visible around the LED.

One approach to prevent the formation of a blue ring around the light-emitting device is disclosed in WO 2006/048064. This reference describes a LED arrangement comprising a LED chip surrounded by a color-converting material, which is arranged on top and on the lateral sides of the LED. A reflector laterally surrounds the color converting material. The maximum distance between the LED chip and the reflector is 0.5 mm. Light emitted on the sides of the LED will be reflected by the reflectors, whereby this light is allowed to convert into white light.

One drawback with the light-emitting device in WO 2006/048064 is that the manufacture of such a device is difficult, time-consuming and expensive. The specific physical shape of the color converting material implies that it has to be formed on site for each one of the light emitting diodes, hence hampering mass production of such devices.

Thus, there is a need in the art to provide an alternative light emitting device which prevents the out-coupling of light that results in the formation of a blue ring, and which therefore provides light with high color homogeneity, the device being easy and inexpensive to manufacture, thereby enabling mass production of such light emitting devices.

### SUMMARY OF THE INVENTION

One object of the present invention is to at least partly fulfill the above-mentioned needs and to provide a light emitting device that emits light with a high color homogeneity, especially where the out-coupling of light resulting in the formation of a blue ring around the light emitting device is avoided.

Another object of the present invention is provide such a light emitting device, which is easy and inexpensive to manufacture, thereby enabling mass production of such light emitting devices.

These and other objects of the present invention are achieved by a light-emitting device and methods for their production according to the appended claims.

Thus, in a first aspect, the present invention relates to a light-emitting device comprising a light emitting diode and a self-supporting wavelength converting element arranged to receive at least part of the light emitted by the light emitting diode.

The wavelength converting element has a flat receiving surface, through which light from the LED is received, an output surface, through which light received by the element can exit the element, and lateral edge surfaces. The edge surfaces are provided with a reflecting material.

In a device of the present invention, light that is emitted by the LED at oblique angles and received by the wavelength converting element will not be able to exit the wavelength converting element through the lateral edges, but will be reflected on the reflecting material an will eventually exit the element through the output surface. Hence, the edge-effect which may lead to the formation of a blue ring around the LED is prevented, and the color homogeneity is improved.

The use of a self-supporting wavelength converting element facilitates the manufacture of the device. The self-supporting elements can be mass produced in bulk, complete with the reflecting material on the lateral edges, and may then at a later stage be arranged on the light emitting diodes to form the light emitting device of the invention. The flat receiving surface yields that the element is simple to produce, since essentially no structural modifications, such as recesses or the like, are needed in that surface.

In embodiments of the present invention, the wavelength converting element may be a flat plate.

Flat plate shaped self-supporting wavelength converting elements, where both the receiving and the output surface are flat, are easy to manufacture as such, hence facilitating mass production of light emitting devices of the present invention.

In embodiments of the present invention, the wavelength converting element comprises an inorganic wavelength converting material.

Inorganic wavelength converting materials are temperature, oxidation and light stable, especially UV/blue light stable. Hence, they will not deteriorate much when exposed to heat, oxygen and/or light. Further, inorganic wavelength converting materials have a high refractive index, which will increase the coupling of light into the wavelength converting material.

In embodiments of the present invention, the wavelength converting element comprises wavelength converting material distributed in an inorganic carrier.

Inorganic carrier materials, such as ceramics or glass materials, are temperature, oxidation and radiation stable. Hence, they will not deteriorate much when exposed to heat, oxygen and/or light. Further, inorganic carrier materials have a high refractive index, which will increase the coupling of light into the wavelength converting element.

In operation, high power LEDs dissipate a lot of energy, both in terms of heat and light intensity. Therefore, it is in connection to such high-power LEDs desired that the wavelength converting material and/or the carrier material is photo-thermally stable, e.g.

inorganic. In a preferred embodiment, both the carrier and the wavelength converting material are inorganic.

In embodiments of the present invention, the reflecting material may be selected from the group consisting of noble and semi-noble metals.

In an addition to good reflection properties, noble and semi-noble metals are stable at elevated temperatures, have a low tendency for oxidation and forms a low diffusion rate barrier, protecting the wavelength converting material from the surrounding atmosphere.

In embodiments of the present invention, the wavelength converting element is arranged on said light emitting diode by means of a bonding layer.

By bonding the wavelength converting element to the light emitting diode, the extraction of light from the LED and the in-coupling into the wavelength converting element may be increased, and at the same time, a rigid structure is obtained. The method of arranging the wavelength converting element on the LED may be facilitated by using the bonding material as an adhesive.

In a second aspect, the present invention relates to a method for manufacturing a wavelength converting element, which generally comprises: providing a wavelength converting element having a light receiving surface, a light output surface, and lateral edge surfaces; and arranging a reflecting material on the lateral edge surfaces.

Wavelength converting elements are self-supporting and can thus be manufactured beforehand and later on arranged on light emitting diodes to form light emitting devices. This facilitates mass production of the light emitting devices of the present invention.

In embodiments of the method of the invention, the self-supporting wavelength converting element is provided by coating the surfaces of a wafer comprising wavelength converting material with a plating-inhibitory composition, and dividing said wafer into a plurality of wavelength converting elements. Thereafter the reflecting material is plated onto said lateral edge surfaces of said wavelength converting element.

Since the lateral edge surfaces of the wavelength converting elements were not coated with the plating-inhibitory composition, these edge surfaces may be plated with the reflecting material, while the receiving and output surfaces will not be plated, due to the inhibitory coating. By this method, several of the steps of the manufacturing method can be performed on a single wafer that thereafter will be divided into a plurality of wavelength converting elements.

In a third aspect, the present invention relates to a wavelength converting element as such, with reflective material arranged on the lateral edge surfaces.

In a fourth aspect, the present invention relates to the manufacture of a light emitting device. The method comprises the steps of providing an LED and thereafter arranging a self-supporting wavelength converting element, having a receiving surface, an output surface and lateral edge surfaces provided with reflecting material, on the LED such that the light receiving surface of the wavelength converting element receives light emitted from the LED.

Since the self-supporting wavelength converting elements can be manufactured beforehand and in a separate process be placed on the LEDs, the device may be easily manufactured.

These and other aspects of the invention will be apparent from and elucidated with reference to the embodiment(s) described hereinafter.

### BRIEF DESCRIPTION OF THE DRAWINGS

FIG. 1 is a schematic view illustrating a light emitting device according to the present invention.

FIG. 2 illustrates a flowchart of the method for manufacturing a light emitting devices according to the present invention.

### DETAILED DESCRIPTION OF THE EMBODIMENTS

The present invention relates to a light emitting device comprising an LED and a self-supporting wavelength converting element, the self-supporting wavelength converting element it self, and methods for the manufacture of the device and the element.

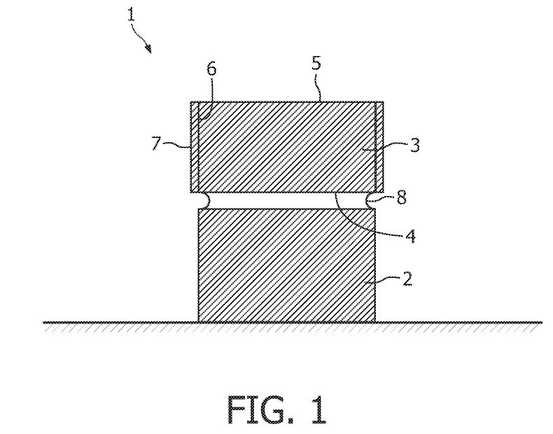

One embodiment of a light emitting device 1 according to the present invention is illustrated in FIG. 1. The light emitting device 1 comprises an LED 2, and a wavelength converting element 3. The wavelength converting element 3 has a light receiving surface 4, an opposing light output surface 5 and lateral edge surfaces 6 provided with a reflecting material 7.

The reflecting material forms edge mirrors on the lateral edge surfaces of the ceramic wavelength converting element.

The wavelength converting element 3 is arranged to receive at least part of the light emitted by the LED 2 and to convert at least a part of the light received into light of a longer wavelength. The wavelength converting element as such forms an especially contemplated aspect of the present invention.

Preferably, the LED 2 is a blue light emitting LED, and the wavelength converting element is adapted to absorb blue light, while emitting yellow light. The combined emission of non-converted blue LED emission and the yellow-converted light gives a white impression.

The wavelength converting element 3 comprises a wavelength converting material that constitutes the element, or is distributed, e.g. dispersed, in a carrier material.

Preferably, the wavelength converting material is an inorganic wavelength converting material. Examples include, but are not limited to YAG-CE, YAG(Gd)-CE, Sr—SiNO:Eu or (BaSr)SiN:Eu (Oxy-Nitride) based materials and any combination of two or more thereof.

Another type of wavelength converting material suitable for use in the ceramic wavelength converting element is a fluorescent material comprising at least one phosphor being an europium(II)-activated halogeno-oxonitridosilicate of the general formula EaₓSi_{y}N_{2/3x+4/3y}:Eu_{z}OₐX_{b}, wherein: 1≦x≦2; 3≦y≦7; 0.001<z≦0.09, 0.005<a≦0.05, 0.01<b≦0.3; wherein Ea is at least one earth alkaline metal chosen from the group of calcium, barium and strontium; and X is at least one halogen chosen from the group of fluorine, chlorine, bromine and iodine.

The term “wavelength converting” as is used herein, refers to a material or element that absorbs light of a first wavelength resulting in the emission of light of a second, longer wavelength. Upon absorption of light, electrons in the material becomes excited to a higher energy level. Upon relaxation back from the higher energy levels, the excess energy is released from the material in form of light having a longer wavelength than of that absorbed. Hence, the term relates to both fluorescent and phosphorescent wavelength conversion.

In embodiments of the present invention, the wavelength converting element is a ceramic wavelength converting element. Such ceramic elements may be prepared from inorganic wavelength converting materials which have been compressed and sintered at high temperatures in order to become ceramic, for example by conventional pressing and sintering methods. The ceramic material may then be grinded and polished to obtain a suitable thickness.

In alternative embodiments, the wavelength converting element comprises a wavelength converting material distributed, e.g. dispersed, in an inorganic carrier material, e.g. glass.

In yet another alternative embodiment, the wavelength converting element may comprise a wavelength converting material distributed, e.g. dispersed, in an organic carrier material, e.g. a polymer. Preferred polymers are essentially optically clear, for example comprising epoxy or silicone resins.

For high-power LEDs, which dissipate a lot of heat, it is preferred that the carrier and/or the wavelength converting materials are inorganic, and more preferred, both are inorganic. Hence, ceramic wavelength converting elements are preferred.

When the reflecting material is applied on the lateral edge surfaces of the wavelength converting element, light will not be able to escape from the edge surfaces of the element. Instead, light incident on the edges is reflected back into the wavelength converting element, allowing for an increased conversion of the light, followed by outcoupling through the light output surface of the element. Thus, the formation of a visible blue ring around the light emitting device is prevented.

The reflecting material provided on the lateral edge surfaces of the ceramic wavelength converting element may be selected any reflecting material, typically a metal, such as a noble or semi-noble metal, for example Ag, Au, Ni, Pd, Pt, Cu, Ir, etc, or combinations and alloys thereof.

The wavelength converting element 3 is bonded to the light emitting diode 2 by means of a bonding material 8, which securely attaches and optically bonds the element 3 to the diode 2.

Preferably, the bonding material is photo-stable, especially UV/blue stable (wavelengths <500 nm) and heat stable.

Further, the bonding layer is preferably optically transparent or translucent, at least for light emitted by the LED.

For good optical coupling, the refractive index should be in the range of from 1.3 to 2, such as from 1.5 to 1.8.

Examples of bonding materials include silanes, polymers and low temperature melting glass materials.

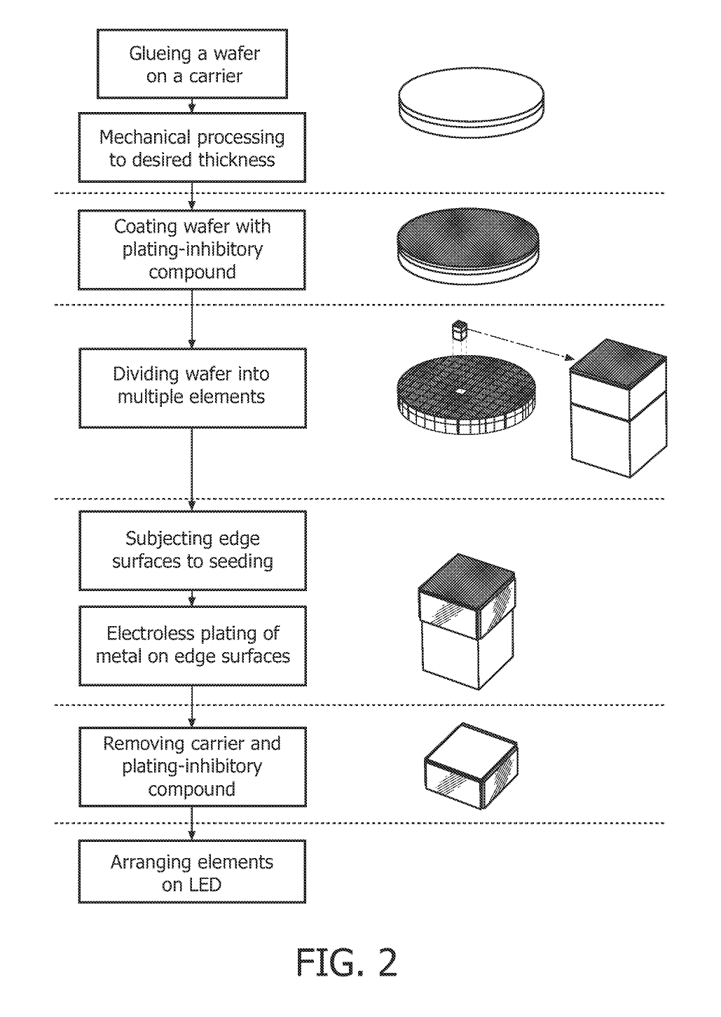

An exemplary method for the manufacture of a light emitting device of the present invention is illustrated in FIG. 2, and illustrates the method for the manufacture of a light emitting device according to the present invention and comprises the steps described below.

In a first part of the method, a ceramic wavelength converting element is provided. This first part it self forms an especially contemplated aspect of the present invention.

In a second part of the method, a ceramic wavelength converting element is arranged on an LED. This second part it self forms an especially contemplated aspect of the present invention.

In the first part of the method, a wavelength converting element is provided and reflecting material is arranged on the lateral edge surfaces of this element.

Typically, the reflective material is arranged on the lateral edge surfaces by means of plating, such as electroless (autocatalytic) plating. According to the exemplary method illustrated in the flow chart of FIG. 2, the method of providing the wavelength converting element starts with providing a wafer, i.e. a large plate, comprising the wavelength converting material.

The wafer is then glued on a carrier, and thereafter the wafer is optionally mechanically processed (grinding, polishing) to the desired thickness.

The surface of the wafer is then coated with a plating-inhibiting compound (an anti-seeding compound) that forms a mono- or multi-layer on the surface, which in a later stage will prevent plating seeds to adhere to the surface of the wafer, thus preventing plating on this surface.

The plating-inhibiting compound may for example be a compound forming a SAM (self-aligned monolayer), silanes or polymers.

Polymers dissolved in a solvent (aqueous or organic) typically form a closed layer after evaporation of the solvent, and silanes/SAM in organic solvent reacts or physically bonds with surface active groups of the wafer.

Other compounds suitable as plating-inhibiting compounds are known to those skilled in the art.

The wafer is then divided (diced) into a plurality of ceramic wavelength converting elements. Each element has a front and a back surface emanating from the front and back surfaces of the wafer (the carrier is still left on either the front or the back surface of the wafer, and lateral edge surfaces. The lateral edge surfaces of the wafer are formed when the wafer is divided into the smaller elements. Hence, the lateral edge surfaces were not exposed to the plating-inhibiting compound, while the front or back surface of the elements was exposed to the anti-seeding solution (the other one of the front and back surface is protected by the carrier).

The wafer may be divided by means of mechanically cutting, laser cutting, sawing, shearing, etc.

Optionally, the elements may be cleaned and dried after the above-mentioned dicing step.

Thereafter, the reflective material is arranged on the lateral edge surfaces on the ceramic wavelength converting element by electroless (autocatalytic) plating.

The wavelength converting elements to be plated are subjected to a seed solution.

The seed-solution comprises a seed-material. One commonly used seed material is Pd. Other seed materials are known to those skilled in the art. The elements may be subjected to the seed solution for example by means of dipping, soaking and spraying.

This seed solution will adhere only to the lateral edge surfaces of the ceramic wavelength converting elements since these have not been subjected to the plating-inhibitory (anti-seeding) compound. Furthermore, the seed-solution is needed for electroless plating to occur.

The ceramic wavelength converting elements are thereafter subjected to an electroless plating solution.

The elements may be subjected to the electroless plating solution for example by means of dipping, soaking and spraying.

The electroless plating solution typically comprises metal (noble or semi-noble metals) to be plated on the surface in form of metal ions, for example as salts, such as sulfate salts.

When in contact with the seeded surfaces, the metal ions are reduced into metal as a film on the surface.

The specific composition of the electroless plating solution will depend on the metal to be plated on the surface and on the wafer material, and will be obvious to those skilled in the art.

The reflecting material of the electroless plating solution forms edge mirrors on the lateral edge surfaces of the ceramic wavelength converting element.

Thereafter, the carrier material and the plating-inhibitory compound are removed from the wavelength converting element, typically by using an organic solvent.

The resulting wavelength converting element has a light receiving surface, an opposing light output surface, and lateral edge surfaces provided with a reflecting material.

The light receiving surface of the wavelength converting element resulting from the method of the present invention may be, but is not limited to, a flat surface. For example, the receiving surface may comprise a recess, preferably a recess which has an area large enough to house the light emitting surface (the top portion) of the light emitting diode, typically such that the receiving surface of the wavelength converting element can extend at least partially down the sides of the light emitting diode on which the element is to be arranged. Other shapes are also possible.

In a second part of the method of producing a light emitting diode, the wavelength converting element, such as produced according to the above, or by any other method, is arranged on an LED.

This can be done immediately after the above-mentioned method. Alternatively, the produced wavelength converting elements are stored for a time before arranging them on an LED.

The wavelength converting element is arranged on the LED such that the receiving surface of the element faces a light emitting surface of the LED, in order to maximize the capability of the element to receive light emitted by the LED.

Typically, the elements are arranged on the LED by means of a bonding layer, as is commonly known to those skilled in the art.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. For example, the present invention is not limited to the use of blue LEDs. In addition, other types of LEDs with different color and wavelength combinations may be used.

In addition, the wavelength converting element is not limited to the application to a specific LED type, but can be applied to all types of LEDs available.

The method of manufacturing the wavelength converting elements from a wafer comprising wavelength converting material is not restricted by a specific wafer thickness or size, but can be varied for different applications.

Further, a single wavelength converting element may be arranged on several light emitting diodes, for converting the light from more than one LED.

1. A light emitting device (1) comprising a light emitting diode (2) and a self-supporting wavelength converting element (3) arranged to receive at least part of the light emitted by said light emitting diode (2), said element (3) having a flat light receiving surface (4), a light output surface (5) and lateral edge surfaces (6), wherein said lateral edge surfaces (6) comprise a reflecting material (7).

2. A light emitting device (1) according to claim 1, wherein said wavelength converting element (3) is a flat plate.

3. A light emitting device according to claim 1, wherein said wavelength converting element comprises an inorganic wavelength converting material.

4. A light emitting device according to claim 1, wherein said wavelength converting element comprises wavelength converting material distributed in an inorganic carrier.

5. A light emitting device (1) according to claim 1, wherein said reflecting material (7) is selected from the group consisting of noble and semi-noble metals.

6. A light emitting device (1) according to claim 1, wherein said wavelength converting element (3) is arranged on said light emitting diode (2) by means of a bonding layer (8).

7. A method for the manufacture of a self-supporting wavelength converting element (3), comprising:
providing a self-supporting wavelength converting element (3) having a flat light receiving surface (4), a light output surface (5) and lateral edge surfaces (6); and
arranging a reflecting material (7) on said lateral edge surfaces (6).

8. A method according to claim 7, wherein said self-supporting wavelength converting element (3) is provided by:
coating the surfaces of a wafer comprising wavelength converting material with a plating-inhibitory compound, and
dividing said wafer into a plurality of wavelength converting elements (3), and wherein said reflecting material (7) is plated onto said lateral edge surfaces (6) of said wavelength converting elements (3).

9. (canceled)

10. A method for the manufacture of a light emitting device (1) comprising:
providing a light emitting diode (2); and
arranging a self-supporting wavelength converting element (3) on said light emitting diode (2), such that the light receiving surface (4) of said ceramic wavelength converting element (3) receives light emitted from the light emitting diode (2), the self-supporting wavelength converting element having a flat light receiving surface, a light output surface and lateral edge surfaces, said lateral edge surfaces comprising a reflecting material.

11. A method for the manufacture of a light emitting device (1) according to claim 10, wherein the ceramic wavelength converting element (3) is bonded to the light emitting diode (2) by means of a bonding layer (8).
